(19) United States
(12) Patent Application Publication
(10) Pub. No.: US 2024/0014255 A1
(43) Pub. Date: Jan. 11, 2024

(54) METAL-OXIDE-SEMICONDUCTOR FIELD-EFFECT TRANSISTOR DEVICE, AND MANUFACTURING METHOD THEREFOR

(71) Applicant: LG ELECTRONICS INC., Seoul (KR)

(72) Inventors: Seung Yup JANG, Seoul (KR); Jaemoo KIM, Seoul (KR); Hojung LEE, Seoul (KR)

(73) Assignee: LG ELECTRONICS INC., Seoul (KR)

(21) Appl. No.: 17/758,339

(22) PCT Filed: Jan. 3, 2020
(86) PCT No.: PCT/KR2020/000115

§ 371 Date: Jul. 1, 2022

(51) Int. Cl. H01L 29/06; H01L 29/16; H01L 29/78; H01L 29/66

(52) U.S. Cl. CPC H01L 29/0607; H01L 29/1608; H01L 29/7811; H01L 29/66712

(57) ABSTRACT

The present disclosure relates to: a MOSFET device that is applicable to a semiconductor device and, particularly, is manufactured from silicon carbide; and a manufacturing method therefor. The present disclosure relates to a metal-oxide-semiconductor field-effect transistor device capable of comprising: a drain electrode; a substrate located on the drain electrode; an N-type drift layer located on the substrate; a first current spreading layer which is located on the drift layer and which has a first doping concentration; P-type wells located on the first current spreading layer, and spaced from each other so as to define a channel; a second current spreading layer which is located between the wells and which has a second doping concentration that is higher than the first doping concentration; a gate oxide layer located on the second current spreading layer and the wells; and a source electrode located on the gate oxide layer.

### TECHNICAL FIELD

The present disclosure is applicable to a semiconductor device, and particularly, relates to a MOSFET device made of silicon carbide and a manufacturing method therefor.

### BACKGROUND ART

Compared to silicon (Si), silicon carbide (SiC) has physical properties such as high breakdown voltage, excellent heat dissipation characteristics, and high temperature operation, and thus a power semiconductor device using SiC has attracted as an alternative to an existing silicon device.

In particular, a silicon carbide MOSFET device made based on these characteristics may propose a solution to replace silicon IGBT (Insulated gate bipolar transistor) and silicon cool MOSFET and to increase power density of a power conversion device.

Accordingly, such a silicon carbide MOSFET device has been actively researched and developed in an application field such as a white good, an electric vehicle, and an ESS (energy storage system).

In order to lower on-state resistance of such a power semiconductor device, a current diffusion layer may be introduced. In this case, the device is usually formed through epitaxial growth or ion implantation.

The current diffusion layer needs to be formed deep enough to cover a p-well layer to properly reduce resistance. However, when the current diffusion layer is formed through ion implantation, it is difficult to form a very deep current diffusion layer due to limit of the maximum ion implantation energy of equipment. Even if the current diffusion layer is formed through ion implantation through an optimized design, it is difficult to avoid damage due to high energy ion implantation.

When the current diffusion layer is formed through epitaxial growth, a sufficiently deep current diffusion layer may be formed, but since the current diffusion layer is formed over an entire wafer area, an unnecessary high doping layer is formed in a chip edge part, and accordingly, breakdown voltage decreases or leakage current increases when a reverse voltage is applied. To this end, an additional process and design improvement are required.

Accordingly, there is a need for a method for sufficiently reducing device resistance through the current diffusion layer without damage to leakage current and breakdown voltage in reverse voltage situations.

### DISCLOSURE

### Technical Problem

An object of the present disclosure is to provide a metal-oxide semiconductor field effect transistor device and a manufacturing method therefor for reducing on-state resistance of a metal-oxide semiconductor field effect transistor device and minimizing degradation in off-breakdown voltage and leakage current characteristics.

An object of the present disclosure is to provide a metal-oxide semiconductor field effect transistor device and a manufacturing method therefor for maximizing an advantage of each of epitaxial growth and ion implantation while using epitaxial growth and ion implantation together when a current diffusion layer of a metal-oxide semiconductor field effect transistor device is formed.

### Technical Solution

As a first aspect for achieving the above object, the present disclosure provides a metal-oxide semiconductor field effect transistor device including a drain electrode, a substrate disposed on the drain electrode, an N-type drift layer disposed on the substrate, a first current diffusion layer disposed on the drift layer and having a first doping concentration, a P-type well layer disposed on the first current diffusion layer and spaced apart from each other to define a channel, a second current diffusion layer disposed between the well layers and having a higher second doping concentration than the first doping concentration, a gate oxide layer disposed on the second current diffusion layer and the well layer, and a source electrode disposed on the gate oxide layer.

The well layer and the second current diffusion layer may be disposed in an active region of the device.

A plurality of P-type ring structures that are spaced apart from each other may be disposed on the first current diffusion layer in an edge region outside the active region.

The first current diffusion layer of the active region and the first current diffusion layer of the edge region may have substantially the same doping concentration.

The ring structures may improve withstand voltage characteristics in the edge region.

A doping diffusion layer may have a doping concentration that does not degrade the withstand voltage characteristics.

The metal-oxide semiconductor field effect transistor device may further include an N+ region adjacent to the channel on the well layer, and a P+ region disposed at another side of the channel.

The first current diffusion layer may be formed via epitaxial growth, and the second current diffusion layer may be formed via ion implantation.

As a first aspect for achieving the above object, the present disclosure provides a metal-oxide semiconductor field effect transistor device including a drain electrode, a substrate disposed on the drain electrode, an N-type drift layer disposed on the substrate, a first current diffusion layer disposed on the drift layer and having a first doping concentration, an active region including a P-type well layer disposed on the first current diffusion layer and spaced apart from each other to define a channel, and a second current diffusion layer disposed between the well layers and having a higher second doping concentration than the first doping concentration, and an edge region outside the active region, wherein the edge region includes a plurality of P-type ring structures disposed on the first current diffusion layer and spaced apart from each other.

The device may further include a gate oxide layer disposed on the second current diffusion layer and the well layer, and a source electrode disposed on the gate oxide layer.

### Advantageous Effects

According to an embodiment of the present disclosure, the following effect may be achieved.

First, excellent electrical properties may be achieved due to improvement in current density in an active region of a device, and simultaneously, withstand voltage characteristics due to a ring structure in an edge region may not be degraded.

According to an embodiment of the present disclosure, current density in an on-state may be increased, and degradation in breakdown voltage and leakage current characteristics in an off-state may be minimized.

According to another embodiment of the present disclosure, additional technical effects that are not state herein may be achieved. The effect may be understood with reference to the specification and the drawings by one of ordinary skill in the art.

### DESCRIPTION OF DRAWINGS

FIG. 1 is a plan view of a metal-oxide semiconductor field effect transistor (MOSFET) device according to an embodiment of the present disclosure.

FIG. 2 is a cross-sectional view of the MOSFET taken along a line A-A according to an embodiment of the present disclosure.

FIG. 3 is a cross-sectional view of a metal-oxide semiconductor field effect transistor device according to an embodiment of the present disclosure.

FIG. 4 is a graph showing on-state resistance in an on-state with an increase in doping concentration based on a JFET distance when only a first current diffusion layer is present.

FIG. 5 is a graph showing breakdown voltage BV in an off-state with an increase in doping concentration based on a JFET distance L_{JFET} when only a first current diffusion layer is present.

FIG. 6 is a graph showing on-state resistance in an on-state based on a JFET distance according to an embodiment of the present disclosure.

FIG. 7 is a graph of breakdown voltage BV in an off-state based on a JFET distance L_{JFET} according to an embodiment of the present disclosure.

FIGS. 8 to 11 are cross-sectional views showing a manufacturing procedure of a metal-oxide semiconductor field effect transistor device according to an embodiment of the present disclosure.

### BEST MODE

Hereinafter, the present disclosure will be described in detail by explaining exemplary embodiments of the present disclosure with reference to the attached drawings.

The same reference numerals in the drawings denote like elements, and a repeated explanation thereof will not be given. The suffixes “module” and “unit” of elements herein are used for convenience of description and thus can be used interchangeably, and do not have any distinguishable meanings or functions. In the following description of the at least one embodiment, a detailed description of known functions and configurations incorporated herein will be omitted for the purpose of clarity and for brevity. The features of the present disclosure will be more clearly understood from the accompanying drawings and should not be understood to be limited by the accompanying drawings, and it is to be appreciated that all changes, equivalents, and substitutes that do not depart from the spirit and technical scope of the present disclosure are encompassed in the present disclosure.

Furthermore, although each drawing is described for convenience of description, it is also within the scope of the present disclosure that those skilled in the art implement other embodiments by combining at least two or more drawings.

When an element, such as a layer, a region, or a substrate, is referred to as being “on” another component, it may be directly on another element or an intervening element may be present therebetween.

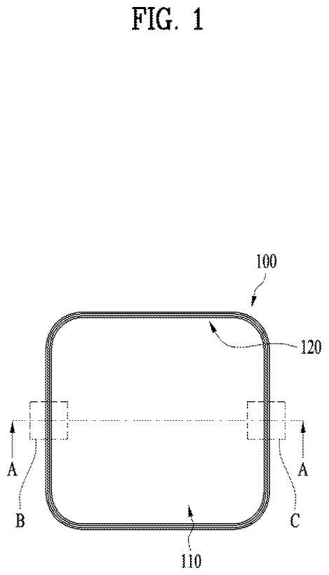

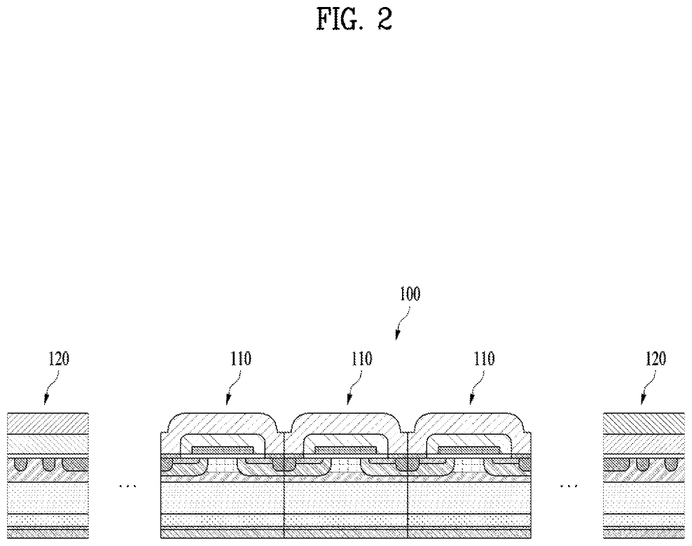

FIG. 1 is a plan view of a metal-oxide semiconductor field effect transistor (MOSFET) device according to an embodiment of the present disclosure. FIG. 2 is a cross-sectional view of the MOSFET taken along a line A-A according to an embodiment of the present disclosure.

Referring to FIGS. 1 and 2, a metal-oxide semiconductor field effect transistor (MOSFET) device 100 according to an embodiment of the present disclosure may include an active region 110 and an edge region 120. Hereinafter, for convenience of description, the metal-oxide semiconductor field effect transistor device 100 is referred to as the MOSFET device 100 for short.

In particular, the present disclosure relates to a silicon carbide (SiC) MOSFET device 100.

Compared to silicon (Si), silicon carbide (SiC) has physical properties such as high breakdown voltage, excellent heat dissipation characteristics, and high temperature operation, and thus a power semiconductor device using SiC has attracted as an alternative to an existing silicon device.

In particular, a silicon carbide MOSFET device made based on these characteristics may propose a solution to replace silicon IGBT (Insulated gate bipolar transistor) and silicon cool MOSFET and to increase power density of a power conversion device. Accordingly, such a silicon carbide MOSFET device has been actively researched and developed in an application field such as a white good, an electric vehicle, and an ESS (energy storage system).

The edge region 120 in a left side of FIG. 2 shows a portion B of FIG. 1, and the edge region 120 in a right side of FIG. 2 shows a portion C of FIG. 1.

The active region 110 may be disposed at a central side of the MOSFET device 100, and as shown in FIG. 2, the structure of the same unit element 110 may be repeatedly disposed. A plurality of ring structures 122b spaced apart from each other may be configured to improve withstand voltage characteristics in the edge region 120. This will be described below in detail. Hereinafter, the active region 110 and the unit element 110 will be described using the same reference numeral.

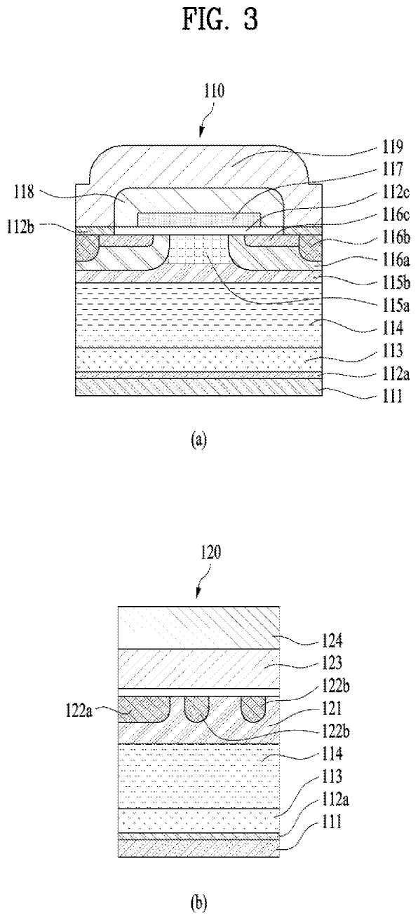

FIG. 3 is a cross-sectional view of a metal-oxide semiconductor field effect transistor device according to an embodiment of the present disclosure.

FIG. 3(a) shows the unit element 110 and FIG. 3(b) shows the edge region 120.

First, with reference to FIG. 3(a), the structure of the separate unit element 110 will be described in detail.

A drain electrode 111 may be disposed at a lower side of the separate unit element 110. A source electrode 119 may be disposed at an upper side of the unit element 110. That is, the separate MOSFET unit element 110 may have a vertical structure in which current flows in a vertical direction of the unit element 110.

A substrate 113 may be positioned on the drain electrode 111. A first contact layer S12a may be disposed between the drain electrode 111 and the substrate 113 to aid contact between the drain electrode 11I and the substrate 113. The first contact layer 112a may be formed of Ni silicide.

A drift layer 114 may be disposed on the substrate 113. The drift layer 114 may be a silicon carbide (SiC) substrate or an epitaxial layer, and for example, may be 4H poly type silicon carbide. Hereinafter, epitaxial growth in the specification may refer to a growth method using a raw material, such as CVD (Chemical vapor deposition).

A first current diffusion layer 115b may be disposed on the drift layer 114. The first current diffusion layer 115b may be formed via epitaxial growth. A first doping concentration that is a doping diffusion layer 115b may be higher than that of the drift layer 114.

P-type well layers 116a that are spaced apart from each other at both sides of the unit element to form (define) a channel may be disposed on the first current diffusion layer 115b. A second current diffusion layer 115a having a second doping concentration higher than the first doping concentration may be disposed between the first current diffusion layer 115b and the well layer 116a.

A gate oxide layer 112c may be disposed on the P-type well layers 116a. In this case, a channel may be formed between the P-type well layers 116a spaced apart from each other and/or a portion at which the P-type well layer 116a is in contact with the gate oxide layer 112c.

An N+, region 116c adjacent to the channel and a P+ region 116b disposed at the other side of the channel may be disposed on the well layer 116a. That is, in the unit element 110 at a portion adjacent to a channel region on the well layer 116a, the two N+ regions 116c may be disposed to be symmetrical to each other based on the second current diffusion layer 115a, and the P+ regions 116b may be disposed outside the N+ region 116c.

Here, the P+ region 116b may have a higher doping concentration than the p-type well layer 116a. That is, P+ may refer to a higher doping concentration than P. Similarly, the N+ region 116c may have a higher doping concentration than the N-type drift layer 114. N+ may refer to a higher doping concentration than N.

In this case, the P+ region 116b may be thicker than the N+ region 116c. The P+ region 116b may be connected to the unit element 110 adjacent thereto. In other words, the P+ region 116b may be disposed at a boundary between the unit elements 110 adjacent thereto.

The P+ region 116b may be a region for maintaining an energy level of the well layer 116a. For example, the P+ region 116b may be a region for maintaining the well layer 116a at a ground level.

A gate layer 117 may be disposed on the gate oxide layer 112c. The gate layer 117 may be formed of poly silicon. The gate layer 117 may be connected to a gate electrode (not shown) through another portion.

The source electrode 119 may be disposed on the gate layer 117. An interlayer dielectric 118 may be disposed between the gate layer 117 and the source electrode 119.

Second contact layer 112b for aiding contact between the source electrode 119, and the P+ region 116b and the N+ region 116c may be disposed at both sides of the gate oxide layer 112c. The second contact layer 112b may be formed of Ni silicide.

The second current diffusion layer 115a may be disposed between the first current diffusion layer 115b and the gate oxide layer 112c. In more detail, the second current diffusion layer 115a may be disposed in contact between the first current diffusion layer 115b and the gate oxide layer 112c.

As such, from an inverted perspective of the unit element 110, the first current diffusion layer 115b may be formed to a depth (thickness) for covering the P-type well layer 116a using an epitaxial growth method.

As described above, the first doping diffusion layer 115b may be higher than that of the drift layer 114 and may be lower than that of the second current diffusion layer 115a.

The second current diffusion layer 115a may be formed via ion implantation. In this case, the second doping concentration of the second current diffusion layer 115a may be set to be higher than the first doping diffusion layer 115b.

For example, the first current diffusion layer 115b may be formed to have a doping concentration of about 8×10⁵ cm⁻³ to 2×10¹⁶ cm⁻³ via epitaxial growth. That is, the first doping concentration may be 8×10¹⁵ cm⁻³ to 2×10¹⁶ cm⁻³.

The second current diffusion layer 115a may be formed to have a doping concentration of about ×10¹⁶ cm⁻³ to 5×10¹⁷ cm⁻³ via ion implantation. That is, the second doping concentration may be 3×10¹⁶ cm⁻³ to 5×10¹⁷ cm⁻³.

Such a manufacturing procedure will be described in detail with reference to the drawings.

In this case, because the first current diffusion layer 115b covers the P-type well layer 116a, current may be diffused through the P-type well layer 116a, and because the second current diffusion layer 115a further reduces resistance of a JFET region (a bottleneck between well layers), device resistance may be further lowered, and the length of the JFET region may be reduced.

Hereinafter, with reference to FIG. 3(b), the structure of the edge region 120 positioned at an edge of the separate unit element 110 will be described.

Referring to FIG. 3(b), the substrate 113 may be disposed on the drain electrode 111. The first contact layer 112a for aiding contact between the drain electrode 111 and the substrate 113 may be disposed between the drain electrode 111 and the substrate 113. The first contact layer 112a may be formed of Ni silicide.

The drift layer 114 may be disposed on the substrate 113. The drift layer 114 may be a silicon carbide (SiC) substrate and an epitaxial layer, and for example, may be 4H poly type silicon carbide.

Layers to the drift layer 114 from the drain electrode 111 in the edge region 120 may be the same as layers of the unit element 110 of the active region 110.

A first current diffusion layer 121 may be disposed on the drift layer 114 of the edge region 120.

A plurality of P-type ring structures (floating field rings) 122b spaced apart from each other may be provided on the first current diffusion layer 121. Although FIG. 3(b) illustrates the two ring structures 122b spaced apart from each other, more ring structures 122b may be provided.

The ring structure 122b may be a component for improving the withstand voltage characteristics of a device in the edge region 120. A doping diffusion layer 121 may have a doping concentration that does not degrade the withstand voltage characteristics of the device.

The first current diffusion layer 121 may be formed via epitaxial growth. The first doping concentration that is a doping diffusion layer 121 may be higher than that of the drift layer 114.

In this case, the first current diffusion layer 115b of the active region 110 and the first current diffusion layer 121 of the edge region 120 may have substantially the same doping concentration. The first current diffusion layer 115b of the active region 110 and the first current diffusion layer 121 of the edge region 120 may be simultaneously formed of the same material.

That is, because the first current diffusion layer 121 is formed via epitaxial growth, the first current diffusion layer 121 may also be formed in the edge region 120 in the same way as the first current diffusion layer 115b of the active region 110.

A doping concentration of the first current diffusion layer 115b of the first current diffusion layer 121 of the edge region 120 may be higher than that of the drift layer 114 but may not degrade the withstand voltage characteristics of the ring structures 122b.

In this case, the second current diffusion layer 115a of the active region 110 is formed through a mask via ion implantation, and thus the second current diffusion layer 115a may not be present in the edge region 120.

The gate oxide layer 112c and an interlayer dielectric 123 may be sequentially disposed on the ring structures 122b. The gate oxide layer 112c and the interlayer dielectric 123 may be simultaneously formed with the gate oxide layer 112c of the active region 110 and the interlayer dielectric 118.

Then, a passivation layer 124 may be disposed on the interlayer dielectric 123.

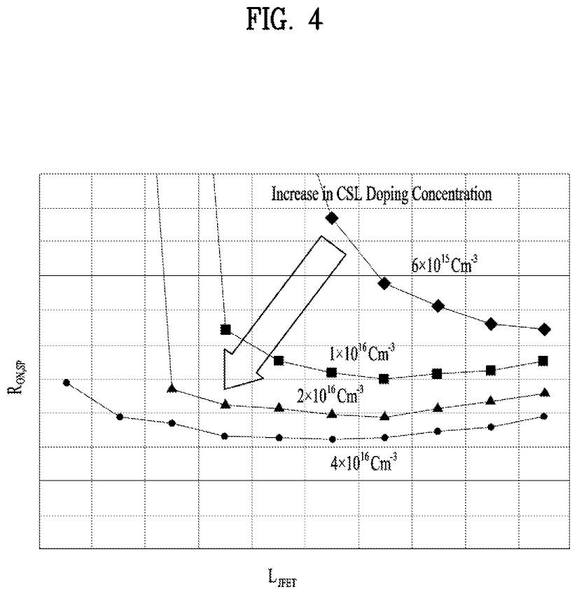

FIG. 4 is a graph showing on-state resistance in an on-state with an increase in doping concentration based on a JFET distance when only a first current diffusion layer is present.

That is, FIG. 4 shows the state of on-state resistance R_{ON} based on a JFET distance L_{JFET} when only a first current diffusion layer formed via epitaxial growth is present in the active region 110. As seen from FIG. 4, as a doping concentration increases, on-state resistance R_{ON} may be remarkably reduced downward.

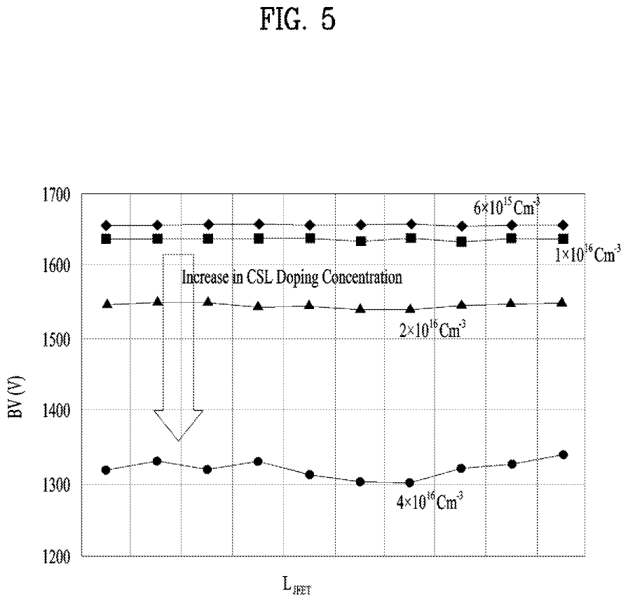

FIG. 5 is a graph showing breakdown voltage BV in an off-state with an increase in doping concentration based on a JFET distance L_{JFET} when only a first current diffusion layer is present. As seen from FIG. 5, similarly, as a doping concentration increases, the breakdown voltage BV may be largely reduced downward.

This means that, as the doping diffusion layer increases, the withstand voltage characteristics are largely degraded. In order to achieve excellent properties of the current diffusion layer in the active region 110, the doping concentration may be increased, but the withstand voltage characteristics due to the ring structures 122b in the edge region 120 may be accordingly degraded largely.

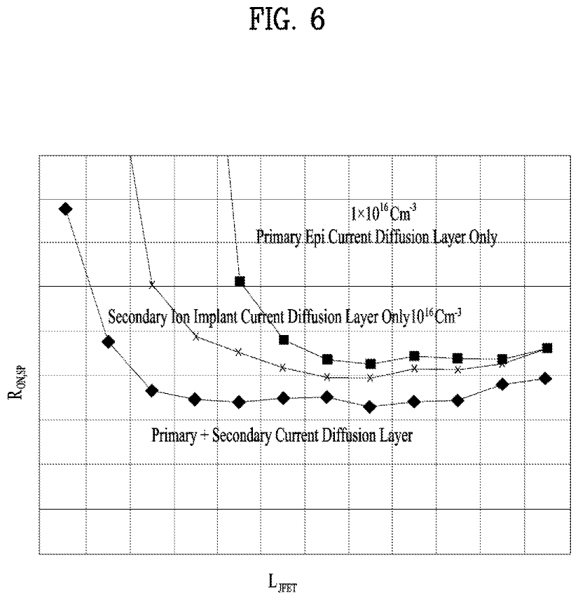

FIG. 6 is a graph showing on-state resistance in an on-state based on a JFET distance according to an embodiment of the present disclosure.

FIG. 6 shows the state of on-state resistance R_{ON} based on a JFET distance L_{JFET} in the case in which only a first current diffusion layer (primary current diffusion layer) is present, the case in which only a second current diffusion layer (secondary current diffusion layer) is present, and the case in which the first current diffusion layer 115b and the second current diffusion layer 115a are configured together (primary+secondary current diffusion layers) like in an embodiment of the present disclosure.

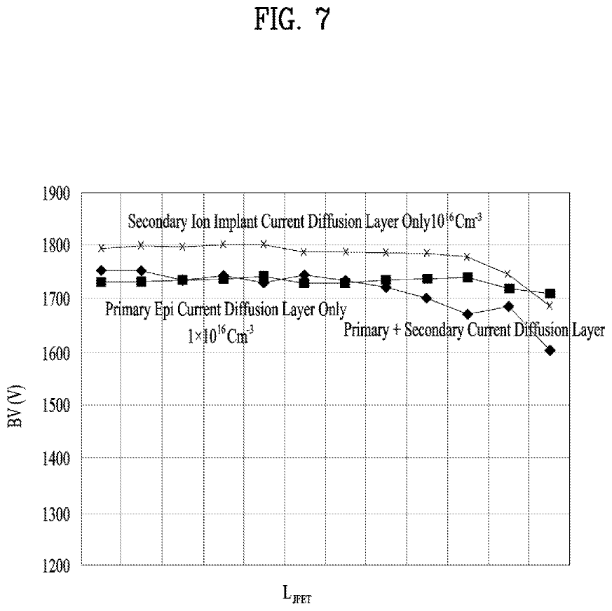

FIG. 7 is a graph of breakdown voltage BV in an off-state based on a JFET distance L_{JFET} according to an embodiment of the present disclosure.

As seen from FIG. 7, the breakdown voltage (BV) may not be largely changed.

That is, according to an embodiment of the present disclosure, it may be seen that, when the first current diffusion layer 115b and the second current diffusion layer 115a are configured together, although the on-state resistance R_{ON} in an on-state is largely reduced like in FIG. 6, the breakdown voltage BV is not largely changed like in FIG. 7.

As such, according to an embodiment of the present disclosure, it may be seen that, excellent electrical properties are achieved due to improvement in current density in the active region 110, and simultaneously, withstand voltage characteristics due to the ring structures 122b in the edge region 120 are not degraded.

As described above, according to an embodiment of the present disclosure, the current density in an on-state may be increased, and degradation in breakdown voltage and leakage current characteristics in an off-state may be minimized.

A conventional current diffusion layer may be generally formed via ion implantation or epitaxial growth. First, when the current diffusion layer is formed via ion implantation, it is disadvantageous in that it is not possible to form the current diffusion layer deeply enough. In contrast, when the current diffusion layer is formed via epitaxial growth, if a doping concentration intends to be increased, the withstand voltage characteristics of an edge region of a device may be disadvantageously degraded, thereby lowering breakdown voltage.

However, according to an embodiment of the present disclosure, current density in on-state may be increased by configuring the first current diffusion laver 115b and the second current diffusion layer 115a together, and degradation in breakdown voltage and leakage current characteristics in an off-state may be minimized.

These characteristics according to the present disclosure may be maximized when the first current diffusion layer 115b and the second current diffusion layer 115a have the above-described doping concentration (the first doping concentration and the second doping concentration) range.

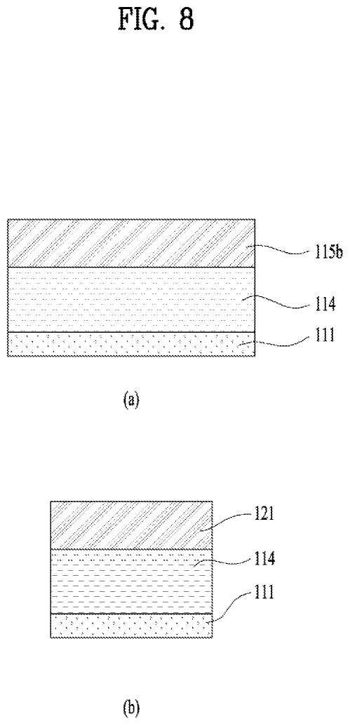

FIGS. 8 to 11 are cross-sectional views showing a manufacturing procedure of a metal-oxide semiconductor field effect transistor device according to an embodiment of the present disclosure.

Hereinafter, with reference to FIGS. 8 to 11, a manufacturing procedure of a MOSFET device according to an embodiment of the present disclosure will be described. In FIGS. 8 to 11, (a) shows a cross section of the active region 110, and (b) shows a cross section of the edge region 120.

First, referring to FIG. 8(a), in the active region 110, the drift layer 114 may be formed on the substrate 113.

The drift layer 114 may be a silicon carbide (SiC) epitaxial layer, and for example, may be 4H poly type silicon carbide. Hereinafter, epitaxial growth in the specification may refer to a growth method using a raw material, such as CVD (Chemical vapor deposition).

The drift layer 114 may become N-type conductive by doping during epitaxial growth.

The first current diffusion layer 115b may be formed on the drift layer 114. The first current diffusion layer 115b may be formed via epitaxial growth. In this case, the first current diffusion layer 115b may become N-type conductive by doping during epitaxial growth. The first current diffusion layer 115b may have conductivity of a first doping concentration, and in this case, the first doping concentration may be higher than that of the drift layer 114

Referring to FIG. 8(b), in the edge region 120, the drift layer 114 may be formed on the substrate 113.

The drift layer 114 may become N-type conductive by doping during epitaxial growth.

The first current diffusion layer 121 may be formed on the drift layer 114.

The drift layer 114 and the first current diffusion layer 121 in the edge region 120 may be simultaneously formed with the drift layer 114 and the first current diffusion layer 115b in the active region 110. Thus, the drift layer 114 and the first current diffusion layer 121 in the edge region 120 may have substantially the same material properties as those of the drift layer 114 and the first current diffusion layer 115b in the active region 110. Here, the “substantially the same” may refer to material properties including a deviation depending on a position when each layer is formed under the same growth condition in growth equipment.

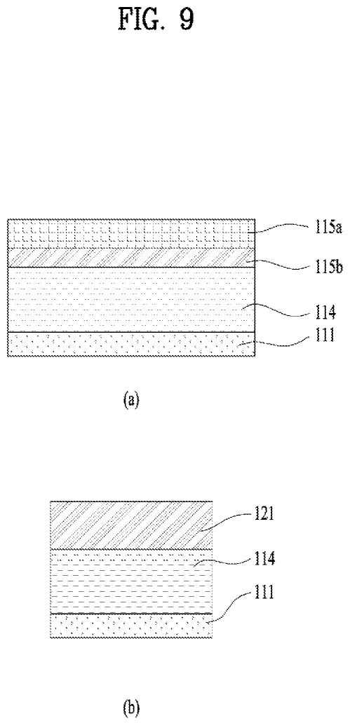

Then, with reference to FIG. 9(a), the second current diffusion layer 115a may be formed on the first current diffusion layer 115b.

The second current diffusion layer 115a may be formed via ion implantation. That is, a portion of an upper side of the first current diffusion layer 115b may be formed as the second current diffusion layer 115a by performing ion implantation on the upper side of the first current diffusion layer 115b.

In this case, through ion implantation, the second current diffusion layer 115a may have a higher second doping concentration than the first doping diffusion layer 115b.

Referring to FIG. 9(b), an ion implantation procedure may not be performed in the edge region 120, and accordingly, the second current diffusion layer 115a having a higher doping concentration than that of the first current diffusion layer 121 may not be formed in the edge region 120.

The first current diffusion layers 115b and 121 may be formed to have a doping concentration of about 8×10¹⁵ cm⁻³ to 2×10¹⁶ cm⁻³ via epitaxial growth. That is, the first doping concentration may be 8×10¹⁵ cm⁻³ to 2×10¹⁶ cm⁻³.

The second current diffusion layer 115a may be formed to have a doping concentration of about 3×10¹⁶ cm⁻³ to 5×10¹⁷ cm⁻³ via ion implantation. That is, the second doping concentration may be 3×10¹⁶ cm⁻³ to 5×10¹⁷ cm⁻³.

When the first current diffusion layers 115b and 121 and the second current diffusion layer 115a have a doping concentration within this range, the current density in an on-state may be increased, and degradation in breakdown voltage and leakage current characteristics in an off-state may be minimized, as described above with reference to FIGS. 6 and 7. That is, the current density in an on-state of the MOSFET device 100 is increased when only the first current diffusion layer 115b is present, but breakdown voltage in an off-state may not be substantially changed compared with the case in which only the first current diffusion layer 115b is present.

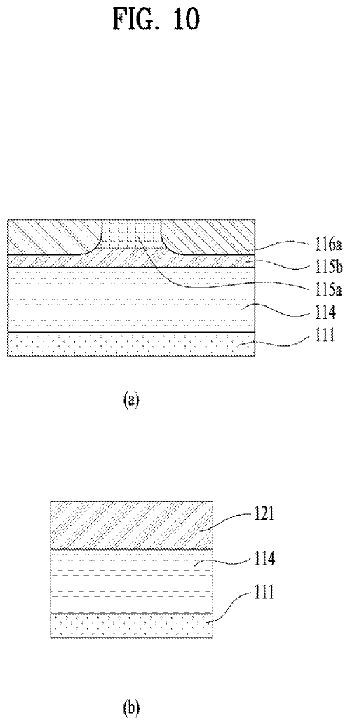

Then, referring to FIG. 10(a), in terms of a unit element, the P-type well layers 116a may be formed at opposite sides of the second current diffusion layer 115a in the active region 110. The P-type well layers 116a may be formed via ion implantation.

Thus, the second current diffusion layer 115a may be disposed between the P-type well layers 116a that are spaced apart from each other at both sides.

Referring to FIG. 10(b), an ion implantation procedure may not be performed in the edge region 120. Thus, in the edge region 120, the first current diffusion layer 121 may be disposed at an upper side.

Then, referring to FIG. 10(a), in the active region 110, the N+ region 116c and the P+ region 116b may be formed on the P-type well layer 116a via ion implantation.

In this case, the N+ region 116c may be formed neighboring the second current diffusion layer 115a. The P+ region 116b may be formed farther from the second current diffusion layer 115a compared with the N+ region 116c. The N+ region 116c and the P+ region 116b may be symmetrical to each other based on the second current diffusion layer 115a in the unit element 110.

In this case, the P+ region 116b may have a higher doping concentration than the p-type well layer 116a. That is, P+ may refer to a higher doping concentration than P. Similarly, the N+ region 116c may have a higher doping concentration than the N-type drift layer 114. N+ may refer to a higher doping concentration than N.

In this case, the P+ region 116b may be thicker than the N+ region 116c. The P+ region 116b may be connected to the unit element 110 adjacent thereto. In other words, the P+ region 116b may be disposed at a boundary between the unit elements 110 adjacent thereto.

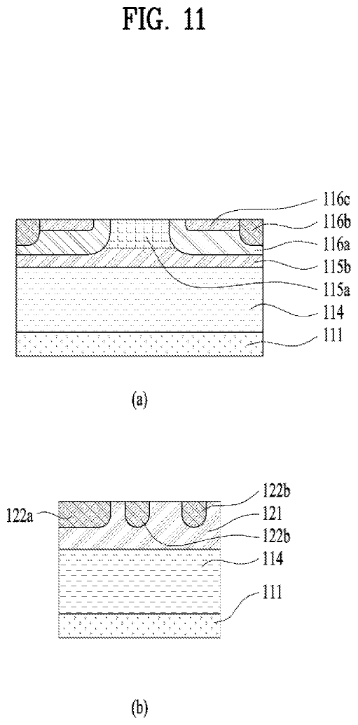

Referring to FIG. 11(b), in the edge region 120, a plurality of P-type ring structures (floating field rings) 122b spaced apart from each other may be formed via ion implantation. Although FIG. 11(b) shows the two ring structures 122b spaced apart from each other, more ring structures 122b may be provided.

The ring structures 122b may be formed by implanting ions to the first current diffusion layer 121. That is, a portion of the first current diffusion layer 121 that is previously formed may be formed as the ring structure 122b via ion implantation. The ring structure 122b may define a P+ region 122a.

In FIG. 11(b), the P+ region 122a disposed at one side of the ring structures 122b may be a portion of the active region, connected to the P+ region 116b. That is, the P+ region 122a of the edge region 120 may be in contract with the P+ region 116b of the active region 110.

The gate oxide layer 112c and the interlayer dielectric 123 may be sequentially disposed on the ring structures 122b. The gate oxide layer 112c and the interlayer dielectric 123 may be formed simultaneously with the gate oxide layer 112c and the interlayer dielectric 118 in the active region 110.

Then, the passivation layer 124 may be formed on the interlayer dielectric 123.

The drain electrode 111 may be formed below the substrate 113 in the active region 110 and the edge region 120. In this case, the first contact layer 112a for aiding contact between the drain electrode 111 and the substrate 113 may be formed between the substrate 113 and the drain electrode 111. The first contact layer 112a may be formed of Ni silicide.

Referring to FIG. 3, the gate oxide layer 112c and the gate layer 117 may be sequentially formed on the second current diffusion layer 115a and the P-type well layer 116a in the active region 110. The gate layer 117 may be formed of poly silicon. The gate layer 117 may be connected to a gate electrode (not shown) through another portion.

The source electrode 119 may be formed on the gate layer 117. The interlayer dielectric 118 may be disposed between the gate layer 117 and the source electrode 119.

The second contact layer 112b for aiding contact between the source electrode 119, and the P+ region 116b and the N+ region 116c may be disposed at both sides of the gate oxide layer 112c. The second contact layer 112b may be formed of Ni silicide.

A MOSFET device including the active region 110 and the edge region 120 shown in FIG. 3 may be formed using such a manufacturing procedure.

The MOSFET device formed using the manufacturing procedure may increase current density in on-state and may minimize degradation in breakdown voltage and leakage current characteristics in an off-state.

These characteristics according to the present disclosure may be maximized when the first current diffusion layer 115b and the second current diffusion layer 115a have the above-described doping concentration (the first doping concentration and the second doping concentration) range.

The above description is merely illustrative of the technical idea of the present disclosure, and various modifications and variations are possible without departing from the essential characteristics of the present disclosure by those of ordinary skill in the art to which the present disclosure pertains.

Accordingly, the embodiments disclosed in the present disclosure are not intended to limit the technical spirit of the present disclosure, but to explain, and the scope of the technical spirit of the present disclosure is not limited by these embodiments.

The scope of the present disclosure should be interpreted by the claims below, and all technical ideas within the scope equivalent thereto should be construed as being included in the scope of the present disclosure.

### INDUSTRIAL AVAILABILITY

The present disclosure may provide a metal-oxide semiconductor field effect transistor device formed of a silicon carbide material.

1. A metal-oxide semiconductor field effect transistor device comprising:
a drain electrode;
a substrate disposed on the drain electrode;
an N-type drift layer disposed on the substrate;
a first current diffusion layer disposed on the drift layer and having a first doping concentration;
a P-type well layer disposed on the first current diffusion layer and spaced apart from each other to define a channel;
a second current diffusion layer disposed between the well layers and having a higher second doping concentration than the first doping concentration;
a gate oxide layer disposed on the second current diffusion layer and the well layer; and
a source electrode disposed on the gate oxide layer.

2. The metal-oxide semiconductor field effect transistor device of claim 1, wherein the well layer and the second current diffusion layer are disposed in an active region of the device.

3. The metal-oxide semiconductor field effect transistor device of claim 2, wherein a plurality of P-type ring structures that are spaced apart from each other are disposed on the first current diffusion layer in an edge region outside the active region.

4. The metal-oxide semiconductor field effect transistor device of claim 3, wherein the first current diffusion layer of the active region and the first current diffusion layer of the edge region have substantially the same doping concentration.

5. The metal-oxide semiconductor field effect transistor device of claim 3, wherein the ring structures improve withstand voltage characteristics in the edge region.

6. The metal-oxide semiconductor field effect transistor device of claim 5, wherein a doping diffusion layer has a doping concentration that does not degrade the withstand voltage characteristics.

7. The metal-oxide semiconductor field effect transistor device of claim 1, further comprising:
an N+ region adjacent to the channel on the well layer; and
a P+ region disposed at another side of the channel.

8. The metal-oxide semiconductor field effect transistor device of claim 1, wherein the first current diffusion layer is formed via epitaxial growth, and the second current diffusion layer is formed via ion implantation.

9. A metal-oxide semiconductor field effect transistor device comprising:
a drain electrode;
a substrate disposed on the drain electrode;
an N-type drift layer disposed on the substrate;
a first current diffusion layer disposed on the drift layer and having a first doping concentration;
an active region including a P-type well layer disposed on the first current diffusion layer and spaced apart from each other to define a channel, and a second current diffusion layer disposed between the well layers and having a higher second doping concentration than the first doping concentration; and
an edge region outside the active region,
wherein the edge region includes a plurality of P-type ring structures disposed on the first current diffusion layer and spaced apart from each other.

10. The metal-oxide semiconductor field effect transistor device of claim 9, further comprising:
a gate oxide layer disposed on the second current diffusion layer and the well layer; and
a source electrode disposed on the gate oxide layer.

11. The metal-oxide semiconductor field effect transistor device of claim 9, wherein the first current diffusion layer in the active region and the first current diffusion layer in the edge region have substantially the same doping concentration.

12. The metal-oxide semiconductor field effect transistor device of claim 9, wherein the ring structures improve withstand voltage characteristics in the edge region.

13. The metal-oxide semiconductor field effect transistor device of claim 9, wherein a doping diffusion layer has a doping concentration that does not degrade the withstand voltage characteristics.

14. The metal-oxide semiconductor field effect transistor device of claim 9, further comprising:
an N+ region adjacent to the channel on the well layer; and
a P+ region disposed at another side of the channel.

15. The metal-oxide semiconductor field effect transistor device of claim 14, wherein the first current diffusion layer is formed via epitaxial growth, and the second current diffusion layer is formed via ion implantation.

16. A method for manufacturing a metal-oxide semiconductor field effect transistor device, comprising:
forming a drift layer on a substrate in an active region and an edge region;
forming a first current diffusion layer on the drift layer in the active region and the edge region;
forming a second current diffusion layer on the first current diffusion layer in the active region;
forming a P-type well layer at opposite sides of the second current diffusion layer in the active region;
forming an N+ region in the P-type well layer neighboring the second current diffusion layer; and
forming a P+ region in the P-type well layer at an edge of the second current diffusion layer.

17. The method for manufacturing a metal-oxide semiconductor field effect transistor device of claim 16, wherein the second current diffusion layer has a higher second doping concentration than the first doping concentration of the first current diffusion layer.

18. The method for manufacturing a metal-oxide semiconductor field effect transistor device of claim 16, further comprising a plurality of P-type ring structures spaced apart from each other in the edge region.

19. The method for manufacturing a metal-oxide semiconductor field effect transistor device of claim 18, wherein the P-type ring structures 122b are formed by implanting ions to the first current diffusion layer.

20. The method for manufacturing a metal-oxide semiconductor field effect transistor device of claim 16, wherein the P+ region is thicker than the N+ region.
